(19) United States
(12) Patent Application Publication
(10) Pub. No.: US 2013/0240027 A1
(43) Pub. Date: Sep. 19, 2013

(54) MULTIJUNCTION HYBRID SOLAR CELL WITH PARALLEL CONNECTION AND NANOMATERIAL CHARGE COLLECTING INTERLAYERS

(71) Applicants: Anvar A. Zakhidov, McKinney, TX (US); Kamil Mielczarek, Murphy, TX (US); Alexios Papadimitratos, McKinney, TX (US)

(72) Inventors: Anvar A. Zakhidov, McKinney, TX (US); Kamil Mielczarek, Murphy, TX (US); Alexios Papadimitratos, McKinney, TX (US)

(73) Assignees: Solarno, Inc., Coppell, TX (US); The Board of Regents of the University of Texas System, Austin, TX (US)

(21) Appl. No.: 13/702,639

(22) PCT Filed: Jun. 7, 2011
(86) PCT No.: PCT/US11/39518

§ 371 Date: May 30, 2013

Related U.S. Application Data
(60) Provisional application No. 61/352,154, filed on Jun. 7, 2010.

(51) Int. Cl. H01L 31/06; H01L 31/18

(52) U.S. Cl. CPC H01L 31/06; H01L 31/1884
USPC 136/255; 438/98

(57) ABSTRACT

A tandem (or multijunction) hybrid photovoltaic device (PV) device comprised of multiple stacked single PVs connected in parallel with each other is described herein. Furthermore, nanomaterials are used as transparent charge collecting electrodes that allow both parallel connection via anode interlayer and also “inverted parallel” connection via cathode type interlayer of different types of solar cells. Carbon nanotube sheets are used as a convenient example for the charge collecting electrodes. The development of these alternative interconnecting layers simplifies the process and may be also used for combined organic PVs with traditional inorganic PVs and Dye Sensitized Solar Cells (DSSC). In addition, novel architectures are enabled that allow the parallel connection of the stacked PVs into monolithic multi-junction PV tandems. This new monolithic parallel connection architecture enables enhanced absorption of the solar spectrum and results in increased power conversions efficiency. Moreover, architectures where cells are stacked monolithically using a series connection can be coupled with cells to create mixed series and parallel connected tandem cells.

### CROSS-REFERENCES TO RELATED APPLICATIONS

This Application claims priority from U.S. Provisional Patent Application No. 61/352,154 filed Jun. 7, 2010, which is hereby incorporated by reference as if fully set forth herein.

### STATEMENT REGARDING FEDERALLY-SPONSORED RESEARCH OR DEVELOPMENT

This invention was made with government support under Grant No. DE-SC0003664 awarded by the Department of Energy. The government has certain rights in the invention.

### BACKGROUND OF THE INVENTION

Multi junction devices, such as tandem solar cells (SCs) permit the harvesting of wider regions of the solar radiation spectrum leading thereby to increases in overall efficiencies. Monolithic inorganic-semiconductor (IN-SC) multi-junction photovoltaic (PV) cells have been demonstrated with one-sun efficiencies in excess of 30%. In fact, the record efficiency of photovoltaic conversion of 40% for non-concentrated solar light is achieved in multijunction devices. In another development, organic photovoltaic cells (OPVs) and dye-sensitized solar cells (DSCs) have shown promise as inexpensive, flexible means for solar energy conversion. The achieved efficiency, ˜11% of single-junction DSCs is already higher than for amorphous Si; current efficiencies of single-junction OPVs are smaller: ˜7-8%. Exploiting OPVs and DSCs in various (organic and inorganic) multi junction architectures is expected to result in increased device efficiencies and could provide a way for balancing performance relative to cost considerations. In conventional IN-SC multi-junction PVs, the single sub-cells are connected electrically in series, and such connection results in increased voltage, but require balanced currents of sub-cells. However, when making multijunctions of OPVs or OPV and IN-SC or OPV and DSSC, the balancing of currents is difficult to achieve, due to the very distinct character of sub-cells. The claimed invention solves the aforementioned problems of the conventional in-series connected PV multijunction devices, such as imbalanced photocurrents by suggesting a novel architecture of alternating parallel and inverted parallel sub-cell electrical connections. Such architecture allows connecting OPV with DSSC or OPV with In-SC using transparent conductive interlayers, for example transparent carbon nanotube films.

There are three types of photovoltaic systems used in present day technology. The widely known inorganic semiconductors, such as silicon, gallium arsenide, cadmium telluride, and others. They are mechanically strong but brittle and chemically unstable, inorganic materials, which are processed by doping, into p/n junctions. They have large diffusion length—(also called “mean free paths”) of free carriers. Photons from the sun directly generate free electron-hole pairs (but not excitons, as discussed below for organic and dye sensitized cells) with large mobility of over 100 and 1000 cm/V²sec. Therefore the thickness of the working photoactive layers is quite large on the scale of tens and hundreds of microns. These p/n junctions are created by high temperature doping processes. Well known multijunction cells are made of series of junction interconnecting solar cells by recombination layers, which are over doped p/n layers functioning as tunneling p++ and n++ layers.

The second type of known photovoltaic system are solar cells made of organic materials such as small molecules and conducting polymers, and are very different from the inorganic semiconductors. The diffusion length of carriers is no more than 100 nm, which is in contrast to inorganic semiconductors where diffusion length is on the scale of tens of microns. Therefore, the thickness of typical solar cells made of organic polymeric molecules is only 100 to 200 nm. Another difference is that the organic solar cells, called OPVs, are excitonic in nature. The solar light is absorbed in the form of neutral excitons which needs to be dissociated before the charge carriers are created to be collected to produce photovoltage or/and photocurrent. This creates a situation that differentiates the solar cells from inorganic solar cells. This type of solar cells needs a donor—acceptor interface to facilitate exciton dissociation. Also required for charge separation in an internal electrical field or special geometry, which is facilitated by the electrodes that are asymmetrical in nature and build an electrical field which separates the carriers in opposite directions. Their combination to multijunction tandems creates many challenges. The thickness is hundred times thicker in case of inorganic materials, because they do not require asymmetrical electrodes, and they also may need p-i-n junctions adjacent to interconnections in hybrid tandems. The claimed invention overcomes this challenge by using nanomaterials that are highly porous networks of nanoscale thin (i.e., approximately 1 to 10 nm) nanomaterials, such as carbon nanotubes, graphene nano-ribbons, and similar materials and we demonstrate how they are used in different approaches.

The third type of known photovoltaic system is called dye sensitized solar cell (DSSC) or Gratzel cell. The nature of this cell is totally different from the two systems described earlier. Sunlight passes through the transparent electrode into the dye layer where it can excite electrons that then flow into the titanium dioxide. The electrons flow toward the transparent electrode where they are collected for powering a load. After flowing through the external circuit, they are re-introduced into the cell on a metal electrode on the back, flowing into the electrolyte. The electrolyte then transports the electrons back to the dye molecules. Therefore, these solar cells have the largest dimensions; usually the scale of titanium oxide photo electrode which is highly porous is about 10 to 20 μm thick. High porosity TiO₂ nanoparticles allows the dye to be attached by special linkers to the surface, and electrolyte—liquid, jell or solid—is embedded into the body of the photoelectrode, and it contacts the opposite counter-electrode so that charge is carried by holes into that counter electrode. The spacing that the electrolyte occupies also varies from tens of microns to possibly hundred of microns, again much larger than 100 nm scale of OPVs. Also, these DSSC solar cells have very different nature as compared to either inorganic cells or to organic PVs; DSSC solar cells have chemically aggressive electrolytes, are of large size, and have a porous photo electrode, which makes it difficult to combine them with organic solar cells. Importantly, the different operational parameters, particularly photocurrents in each type of solar cell make it difficult to combine them into one in-series multijunction. The claimed invention solves these problems and allows the combination of p/n inorganic, OPV and DSC into multijunction tandem solar cells.

### SUMMARY OF THE INVENTION

The present invention is directed to the combination of solar cells of different types into multijunction tandems using nanomaterials and chemically stable nano-structures that are transparent to optical light and conduct electricity. First, the present invention combines the geometry of parallel electrical connections which is used sometimes in combination with series connection in such a way that current from parallel connection are added to each other and there is no need to balance the photo current. This is important because the current generated in inorganic semiconductors are in the range of 30 to 50 mA/cm², while in organic solar cells the typical current is between 5 to 15 mA/cm², which is about 10-15 times lower. Secondly, the advantage of the claimed invention lies in using special nanomaterials which are forms of carbon, such as carbon nanotubes, graphene ribbons, and graphene oxide is that they are extremely chemically robust, and mechanically strong. Third, in the claimed invention, electrodes and interlayer of tandem structures are inverted, which is achieved by special type of doping by organic materials, selective barriers or transport layers, that allows converting a cathode to anode, and enables parallel connections.

The invention relates to a new type of architecture for OPVs or hybrid tandem or multijunction photovoltaic (PV) solar cells (made of organic or excitonic or inorganic or other sub-cells) in which the separate constituent single junction PV devices are connected in a new type of alternating “inverted parallel electrical connection”, distinct from conventional in-series tandem connections, or recently reported by us conventional parallel connection tandem. More specifically, this invention relates to inverted parallel tandems with transparent interlayers which are inverted from being conventional anodes (holes) to become cathodes (electron collectors) between the top and bottom sub-cell devices in such a way that the total current in the tandem is increased, compared to electrical current in each part. These inverted interlayers are in the form of nanofibrous electrodes for photovoltaic cells (and also for photodetectors), made of organic materials and hybrid organic-inorganic structures, such as carbon nanotube transparent sheets with appropriate functional coatings or nanocomposites of carbon nanotubes with fullerenes or functional polymers.

Methods, processes and architectures are described for creating inverted parallel tandems in the present invention, which incorporate transparent carbon nanofiber sheets, or other transparent conductors (such as ITO, ZnO, etc.) as active charge collecting transparent electrodes in organic, hybrid and plastic thin film devices, such as multijunction (also called alternating inverted parallel-connection) solar cells, photodetectors and other similar electronic and optoelectronic devices. Additional features of active interlayer charge collectors in inverted parallel tandems such as enhancement of light absorption and charge photogeneration due to antenna effects, such as selective absorption (due to a plasmon resonance in the interlayer of light absorbed in desired spectral bands) in PV solar cells, and other advantages are described.

The claimed invention is a novel OPV multijunction solar cell design that is of low weight and flexible and at the same time can generate a high power conversion efficiency, meeting or exceeding the goal of 10% efficiency. This design exploits the concept of a tandem architecture with ultrastrong carbon nanotube (CNT) sheets for charge collection; this unique approach combines the advantages of different regions of solar spectrum absorption from different organic electron donor/photoactive materials and highly conductive carbon nanotube sheets providing three-dimensional charge collection. The organic PV tandem solar cells are composed of two or more different conjugated polymer/PCBM heterojunction or small molecule/C60 solar cells. The proposed tandem or multijunction cell can be fabricated on a lightweight plastic substrate, and the resulting photovoltaic material can be stored in roll form and unfurled or deployed anytime under sunlight to generate power.

A general advantage of the tandem structure is its multiple absorption ranges. The wavelength distribution of the solar spectrum has a wide range, covering the UV to IR. Although there are many kinds of inorganic and organic materials that are used as photoactive layers of PV cells, the individual materials have specific and narrow absorption ranges. Hence, only a part of the solar spectrum is effective in generating the photo carriers in a single junction PV cell. By using materials with a different absorption range for each PV cell of the tandem or multijunction structure, the total absorption range of the tandem OPV cell can be the superposition of the each PV material.

The claimed invention is a truly innovative approach, involving the use of transparent carbon nanotube (CNTs) sheets as an interlayer, converting this interlayer into a cathode, connecting the two (or more) PV sub-cells in a monolithic architecture with a novel alternating inverted parallel connection in which photocurrents of each sub-cell add to increase the overall power conversion efficiency. Moreover, inverted CNT sheet cathode provides three-dimensional structure to increase the contact area between electrode and photoactive layer, and electrons do not have to travel all the way to electrode/photoactive layer interface to be collected. Thus, this can provide current enhancement resulting in increase in overall power conversion efficiency by more efficient charge collection. In an OPV, the diffusion length of photogenerated charges is small (only ˜100 nm before electron and hole recombine), and the use of three dimensional CNT charges collectors with spacing between nanotubes smaller than above mentioned 100 nm length, allows to better collect charges before recombination.

Therefore, the goal of this invention is to create prototypes of flexible, thin-film high efficiency hybrid solar cell tandems consisting of multilayer organic OPV (polymeric and small molecule), DSSC and inorganic solar cells, with broad spectral sensitivity to the solar spectrum

### BRIEF DESCRIPTION OF THE DRAWINGS

FIG. 1 represents A) Conventional series OPV tandem connection; B) the concept of a parallel tandem with nano material (CNT) active interlayer as cathode; and C) new concept of inverted parallel tandem with nano material (CNT) anode interlayer.

FIG. 2 represents a hybrid tandem solar cell based on transparent carbon nanotube networks having various topologies, as interlayers between DSSC, inorganic and OPV solar cells for maximal collection and recombination of charges.

FIG. 3 represents (A) Photograph of MWCNT forest with sheet being drawn from it; (B) SEM image of SWCNT sheet; (C) SEM image of MWCNT sheet densified on substrate; and (D) SEM image of MWCNT sheet with better interconnectivity.

FIG. 4 represents A) a tandem solar cell comprised of inorganic/DSSC/OPV solar cells with a transparent cathode; and B) a tandem solar cell comprised of inorganic/DSSC/OPV solar cells with a transparent anode.

FIG. 5 represents A) an inverted tandem solar cell comprised of inorganic/DSSC/OPV solar cells with a transparent anode; and B) an inverted tandem solar cell comprised of inorganic/DSSC/OPV solar cells with a transparent cathode.

FIG. 6 represents A) a tandem solar cell comprised of inorganic/OPV/DSSC solar cells with a transparent anode; and B) a tandem solar cell comprised of inorganic/OPV/DSSC solar cells with a transparent cathode.

FIG. 7 represents A) an inverted tandem solar cell comprised of inorganic/OPV/DSSC solar cells with a transparent anode; and B) an inverted tandem solar cell comprised of inorganic/OPV/DSSC solar cells with a transparent cathode.

FIG. 8 represents A) a tandem solar cell comprised of OPV/inorganic/DSSC solar cells with a transparent anode; and B) a tandem solar cell comprised of OPV/inorganic/DSSC solar cells with a transparent cathode.

FIG. 9 represents A) an inverted tandem solar cell comprised of OPV/inorganic/DSSC solar cells with a transparent anode; and B) an inverted tandem solar cell comprised of OPV/inorganic/DSSC solar cells with a transparent cathode.

FIG. 10 represents A) a tandem solar cell comprised of DSSC/OPV/inorganic solar cells with a transparent anode; and B) a tandem solar cell comprised of DSSC/OPV/inorganic solar cells with a transparent cathode.

FIG. 11 represents A) an inverted tandem solar cell comprised of DSSC/OPV/inorganic solar cells with a transparent anode; and B) an inverted tandem solar cell comprised of DSSC/OPV/inorganic solar cells with a transparent cathode.

FIG. 12 represents A) a tandem solar cell comprised of OPV/DSSC/inorganic solar cells with a transparent anode; and B) a tandem solar cell comprised of OPV/DSSC/inorganic solar cells with a transparent cathode.

FIG. 13 represents A) an inverted tandem solar cell comprised of OPV/DSSC/inorganic solar cells with a transparent anode; and B) an inverted tandem solar cell comprised of OPV/DSSC/inorganic solar cells with a transparent cathode.

FIG. 14 illustrates a hybrid parallel tandem structure between a Solid State Dye Sensitized Solar Cell (SS-DSSC) sub cell (111) and a bulk heterojunction organic photovoltaic (OPV) sub-cell (112) connected in parallel through common anode (105).

FIG. 15 represents the band diagram of a hybrid parallel tandem solar cell comprised of a SS-DSSC and an inverted OPV solar cell.

FIG. 16 illustrates the inverted hybrid parallel tandem architecture between a Solid State Dye Sensitized Solar Cell (SS-DSSC) sub-cell (211) and a bulk heterojunction organic photovoltaic (OPV) sub-cell (212) connected in parallel through common cathode (205).

FIG. 17 represents the band diagram of a hybrid parallel tandem solar cell comprised of a DSSC and an inverted OPV solar cell.

FIG. 18 represents a series tandem solar cell comprised of two OPV sells with p-i-n architecture, doped charge transport layers and CNT interlayer.

FIG. 19 represents the band diagram of a series tandem solar cell comprised of two OPV sells with p-i-n architecture, doped charge transport layers and CNT interlayer.

FIG. 20 represents a parallel tandem solar cell comprised of two OPV sells with p-i-n architecture, doped charge transport layers and CNT interlayer.

FIG. 21 represents the band diagram of a parallel tandem solar cell comprised of two OPV sells with p-i-n architecture, doped charge transport layers and CNT interlayer.

FIG. 22 illustrates the CNT sheet dry-drawing process from the vertically oriented CNT forest and CNT sheet lamination process on an OPV device or substrate.

FIG. 23 represents A) the actual structure of an organic parallel tandem; and B) the top view and side view of OPV tandem and the sequence of layers.

FIG. 24 represents A) the structure of a parallel tandem OPV with a common anode interlayer; B) absorption spectra of PCPDTBT, P3HT, and SOEH-PPV materials that are used as donor materials in parallel tandem OPV cells; and C) energy diagram of parallel tandem OPV with a common anode interlayer.

FIG. 25 represents A) the structure of a parallel tandem OPV with a common cathode interlayer; and B) energy diagram of parallel tandem OPV with a common anode interlayer and inversion layers.

FIG. 26 represents A) a three junction OPV with alternating inverted parallel connection; and B) four junctions OPV with 4 sub-cells with alternating inverted parallel connections.

FIG. 27 illustrates the operation of an OPV-DSSC tandem solar cell of in-series architecture

FIG. 28 shown the band diagram for in-series tandem solar cells of DSSC and OPV interconnected by CNTs

FIG. 29 represents A) the structure of a parallel tandem OPV (polymeric and small molecule sub cells) with a common cathode interlayer; and B) energy diagram of parallel tandem OPV with a common anode interlayer and inversion layers.

### DESCRIPTION OF EXEMPLARY EMBODIMENTS

Demonstrated tandem devices with conventional OPVs are composed of stacked individual cells, each built on a substrate using a separate set of electrodes, which electrically connected as non-monolithic device. Monolithic structures with two OPVs are reported, which used metal or solution-processed metal oxides as an interlayer between constituent OPV cells. Combining SCs whose operation is based on different physical concepts in a monolithic structure, e.g., OPV-DSSC or OPV-Inorganic-SC proposed here is possible due to use of innovative nanomaterials: e.g. CNT sheets which connect top and bottom cells by novel inverted parallel connection (contrary to conventional in-series connection) and also contrary to previously described interconnects, which are only anodes, i.e. collect holes.

The new type of connection in inverted parallel tandems is not possible with previously known bulk materials. Strong transparent sheets of carbon nanotubes with additional inversion layers allow the new type of inverted parallel connections, since it permits the attachment of the outer lead to the interconnect, (while in previous in-series connection the outer leads were not needed). A tandem OPV cell with a transparent titanium oxide layer has been reported and it was fabricated by all-solution processing. All of the previous reports were focused on the tandem OPV cell with series connection. An obvious property of the series connection is an increased V_{OC}. The V_{OC} of a tandem cell with series connection is expected to be the sum of the V_{OC} of each individual cell. In contrast, the parallel connection has an increased short circuit current density (J_{SC}). The total J_{SC} in the parallel configuration is the sum of J_{SC} contributed by each individual cell. As an intermediate layer for the thin film tandem OPV, it needs to be thin and smooth enough to prevent short circuit. In the present invention, we show that alternating parallel connections can be possible by inverting the parallel connecting interconnecting layer, and as a result of this triple, four sub-cell, and more sub-cell multi-junctions become possible. Thus, typical intermediate layers for the series tandem OPV are an ultra thin layer of metal or oxide. These intermediate layers are a kind of “floating” layer in the OPV structure. These layers cannot be connected with an external circuit directly. For the alternating inverted parallel OPV multijunction cells, an intermediate layer, which can be connected directly from the external circuit, is needed. The present invention is directed to such a new design and architecture.

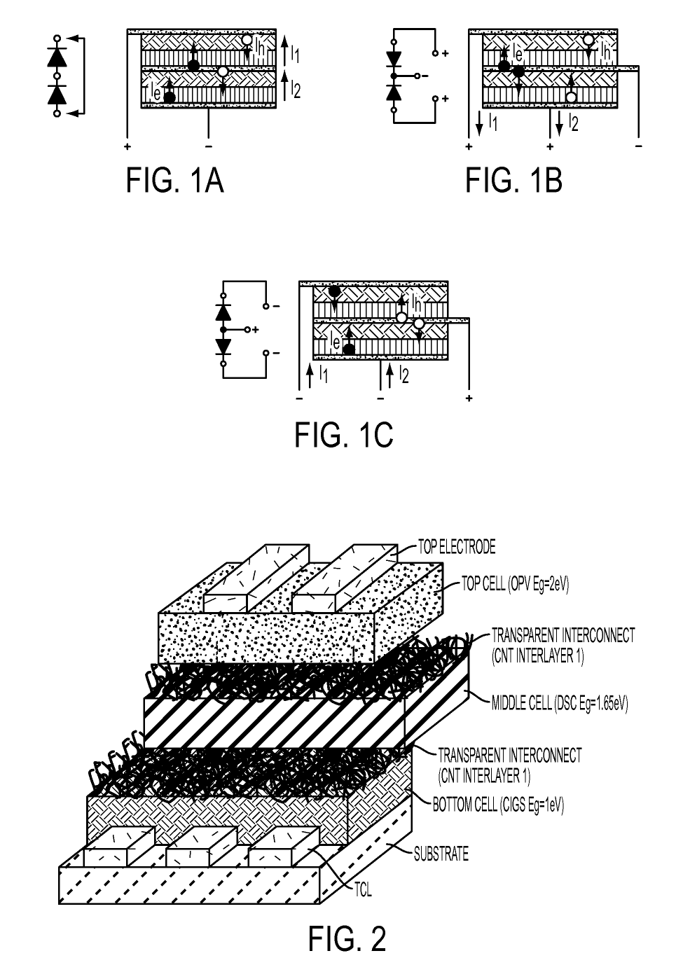

In conventional in-series connected cells in a PV tandem, the holes are located in the bottom cell, while electrons are arriving from the top cell (FIG. 1A) so the transfer of the charge at the interface in a monolithic tandem requires that the holes recombine with the electrons (so charges should be balanced). The voltages of top and bottom cells add in series tandem architecture, while only the lowest electrical current can pass through in-series tandem, and current balancing is required. In contrast, for the suggested here parallel tandem the photocurrent is the sum of the photocurrents of each cell (I=I_{bot}+Iₜₒₚ) and is collected with the charge collecting electrode, while the average photovoltage is generated. In FIG. 1B the parallel tandem architecture is illustrated with an interlayer that is a common cathode for top and bottom units. In addition, it possible to fabricate such architecture with a common interlayer that functions as a common anode (FIG. 1C).

In an embodiment of the invention, advantages of Parallel Tandem Compared to Series Tandem Configuration include the following: (1) does not need the current balancing; (2) can connect PVs with very different photocurrents I_{sc}, but similar photovoltages V_{oc.}; (3) the transparent interlayer plays a role of a charge collector layer (interlayer) and is an active electrode, i.e. is connected to outcoming leads and therefore should have low serial resistance; and (4) interconnecting electrodes made of continuous strong materials should be used, e.g. such as nanofibrous films, CNT sheets etc. As an example here, the transparent carbon nanotubes are described as an active interlayer since it needs to be continuous (contrary to flakes of charge recombining interlayers in conventional in-series connections).

FIG. 2 illustrates a hybrid tandem consisting of solar cells with different nature. Flexible transparent carbon nanotube networks having various topologies and surface functionalization as are used as interlayers between DSSC, p/n inorganic (e.g., CIGS) and OPV layers (based on materials such as polymeric P3HT:PCBM or small molecule CuPc:C60 or others) for maximal collection and recombination of charges. A bottom electrode is deposited on top of the substrate follow by a bottom inorganic solar cell (such as CIGS, CdTe and Si). Next, the first interlayer of nanomaterial (such as CNT sheets) is deposited as interlayer with the second cell of the tandem structure. A dye sensitized solar cell is used at the middle cell. Another layer of nanomaterials is applied as the second interlayer between the second and third sub-cells. The third cell of the tandem is an organic solar cells that may be fabricated be vacuum or solution process. Finally, a top electrode is fabricated. The use of different types of solar cells increases spectral sensitivity to the solar spectrum. OPV cells have wide band gap of approximately 2 eV, while DSSC and inorganic cells have smaller band gaps of about 1.65 eV and 1 eV respectively. This is important because the currents generated in inorganic semiconductors are in the range of 30 to 50 mA/cm², while in organic solar cells the typical current is between 5 to 15 mA/cm², which is about 10-15 times slower.

An advantage of parallel electrical connectivity compared to series connections is the combination of different types of cells. The device currents also could be very different but it is very important, when solar cells which are different in nature are combined. If connected in series only, the smallest current can go through the whole device. That means the big current of inorganic p/n cell will be lost. In contrast, if they are connected in parallel, the currents will be added to each other, but the voltage needs to be similar. Fortunately, all three different solar cells types have comparable band gaps.

A second advantage is the fact that we created special type of inversion, so the central common electrode—common anode and cathode of parallel connection—can work effectively. An electrode that is usually an anode can be converted into a cathode, and then the entire solar cell structure is inverted by incorporating additional functional of layers around common electrode. There are two types of inversion layers. Inversion can be done by selection of inorganic material (called blocking material or charge transport material). For example, a layer of an oxide (such as ZnO or others) can facilitate electron extraction from the cell to an electrode of CNT sheets. On the other side when a layer of molybdenum oxide, which is hole transport material and electron blocking material, low work function metals are inverted to anodes. This selectivity allows solar cell inversion and makes it compatible for parallel architecture.

A third advantage and most important of the present invention that also differentiates from previous work reported is the use of very small sized nano-conductive nanomaterials as the transparent conductive electrodes. The fact, that materials like carbon nanotubes or graphene ribbons have very small dimension ranging from 1 nm to 10 nm, and highly porous with open porosity of about 50 to 100 nm allows the light to go through, but electrons are conducted through a three dimensional network of tiny nanowires. Moreover, not only the nano scale and size of nanomaterials is very important for this type of connectivity, but also the fact that carbon is very chemically inert, therefore is stable makes the carbon nanotubes, probably, the best material to connect dye sensitized solar cells, which always have aggressive chemical nature of electrolytes. It is important to protect the layers which are degraded from the aggressive nature of electrolyte ions. Carbon nanotubes have been proven to be excellent counter electrodes for DSSCs, because they do not degrade due to the electrolyte. Thus, it is possible to deposit carbon nanotubes using the method of biscrolling or by rolling any other functional materials which are useful in tandem solar cells.

An embodiment of the invention describes the use of carbon nanotubes for titanium oxide coating which acts as photoelectron of DSSC cells. On the other side, it is not coated—but active—just as an electron collecting layer; however, it can also be coated by electron transport layer such as zinc oxide or other inorganic oxides.

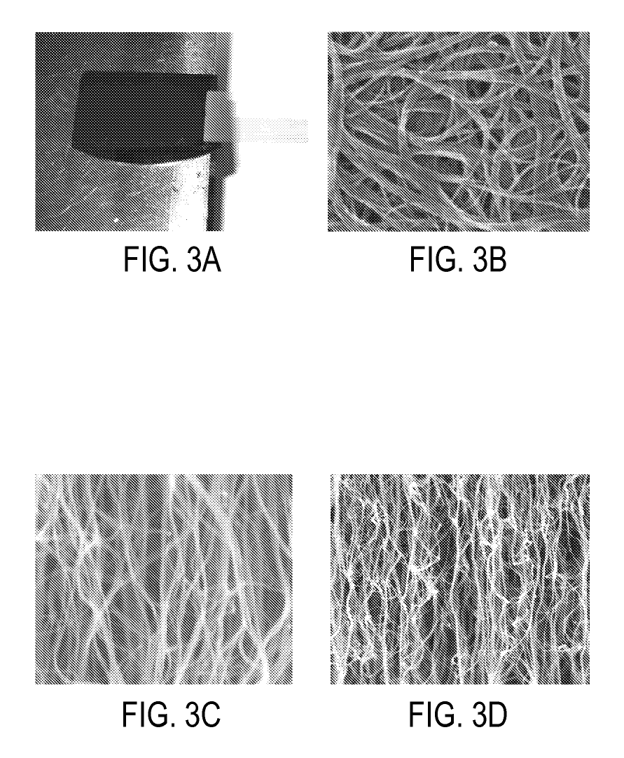

The CNT sheets can be drawn into free-standing state prior to deposition on top of a substrate or active layer. FIG. 3A shows the formation of CNT sheets from a CNT forest. The growth of CNTs and formation of the CNT forest is through a Chemical Vapor Deposition (CVD) process and is done in a furnace. The forest can be drawn out and transferred as free standing CNT sheets. The dry process is described in greater detail below. The technology is compatible with both single wall carbon nanotube sheets (SWCNT) and multi wall carbon nanotube sheets (MWCNT). FIG. 3B shows an SEM image of SWCNT sheet. An SEM image of MWCNT sheet densified on substrate is shown in FIG. 3C. The properties of CNT sheets are dependent of the growth properties of CNT forest and processing of CNT sheets. An SEM image of MWCNT sheet with improved interconnectivity is shown in FIG. 3D.

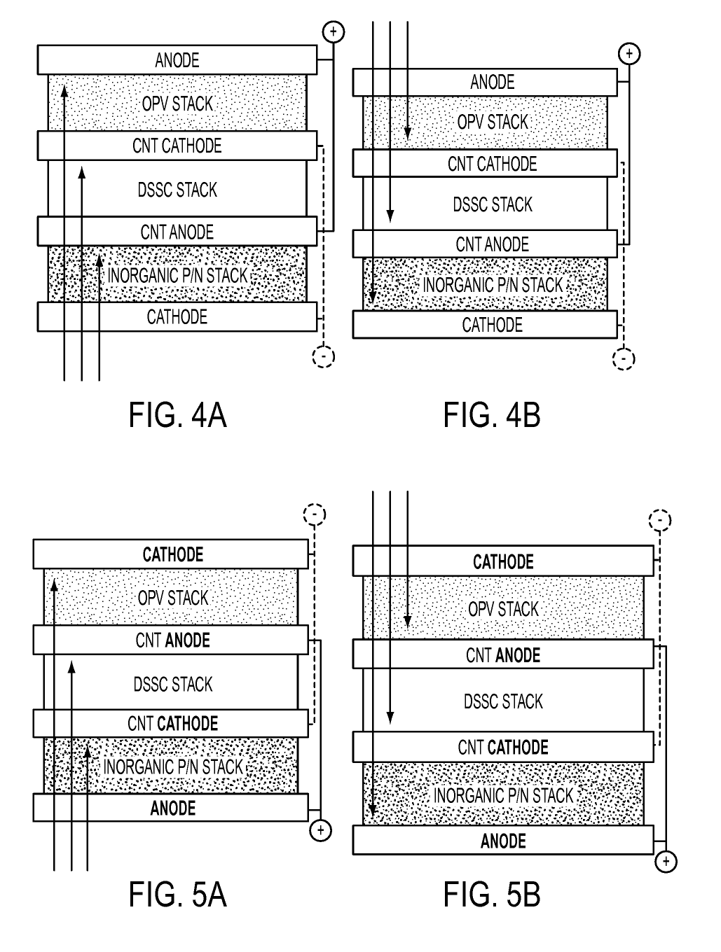

The claimed invention can be applied to fabricate multiple variations of the structure shown in FIG. 2. The easy processing of CNT sheets and their multifunctionality as cathodes or anodes facilitates the fabrications of new solar cell device architectures. In FIG. 4A, a triple parallel hybrid tandem with different types of cells is shown. A transparent cathode (made of transparent conductive oxide) is deposited on a substrate followed by an inorganic solar cell (such as Si, CdTe , CIGS or other inorganic semiconductor). A CNT sheet is applied to form a common anode with the middle DSSC sub-cell. The CNT sheet may be placed between appropriate inversion layers. A second CNT interlayer is deposited as a common cathode between the DSSC and top OPV cells. The OPV cell may be solution processed and have an acceptor—donor materials such as forming bilayers or bulk heterojunctions of P3HT:PCBM or PCPDTBT:PCBM. In addition, the cell can be fabricated by vapor deposition (consisting of multiple layers such as CuPc:C60 and ZnPc:C60). On top, an anode electrode is deposited. The use of transparent cathode and transparent substrate allows the illumination of the threes cells from the bottom side. In addition, it is possible to fabricate an inverted version of this hybrid tandem. The bottom cathode is fabricated on top of a non transparent substrate. The three sub-cells are then fabricated in the same order as earlier with the corresponding CNT interconnecting layers. Finally, a top transparent anode is fabricated to allow illumination of the hybrid tandem from the top (FIG. 4B).

In FIG. 5A, a variation of the triple parallel hybrid tandem is shown. A transparent substrate is used to fabricate the device. A transparent anode (made of transparent conductive oxide such as ITO) is deposited on a substrate followed by an inorganic solar cell (such as Si, CdTe, CIGS or other inorganic semiconductor). A CNT sheet is applied to form a common cathode with the middle DSSC sub-cell. The CNT sheet may placed between appropriate inversion layers. A second CNT interlayer is deposited as a common anode between the DSSC and top OPV cells. On top, a cathode electrode is deposited made of low workfunction metal or oxide metal bilayer. The use of a transparent anode and substrate allows for the illumination of the threes cells from the bottom side. In addition, it is possible to fabricate an inverted version of this hybrid tandem. The bottom anode (such as Au) is fabricated on top of a non transparent substrate. The three sub-cells are then fabricated in the same order as earlier with the corresponding CNT interconnecting layers. Finally, a top transparent cathode is fabricated to allow illumination of the hybrid tandem from the top (FIG. 5B).

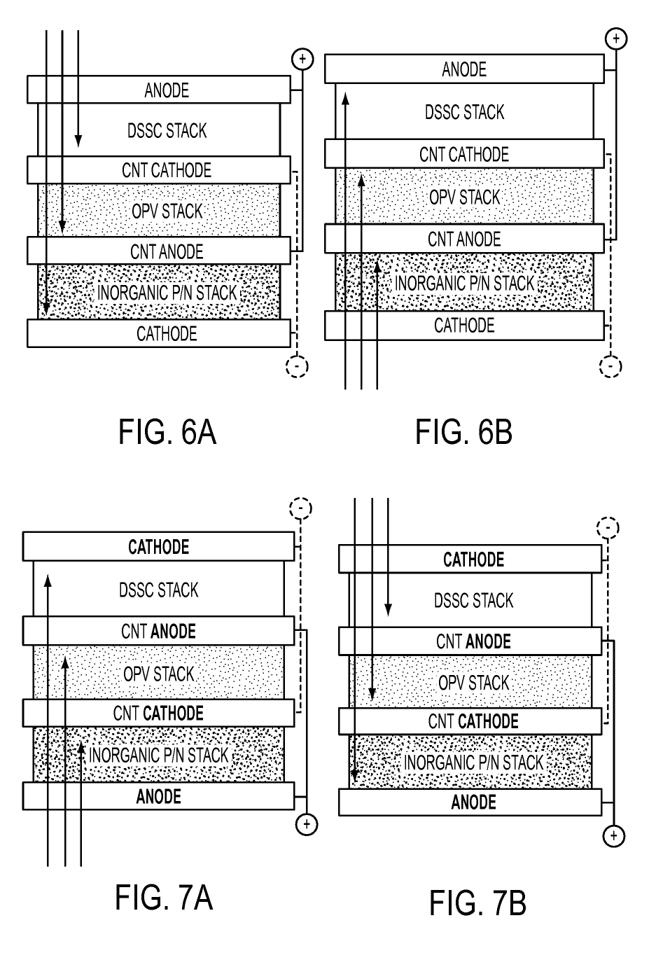

In FIG. 6B, a triple parallel hybrid tandem with different types of cells is shown. A transparent cathode (made of transparent conductive oxide) is deposited on a substrate followed by an inorganic solar cell (such as Si, CdTe, CIGS or other inorganic semiconductor). A CNT sheet is applied to form a common anode with the middle OPV sub-cell. The CNT sheet may be placed between appropriate inversion layers (MoO₃). A second CNT interlayer is deposited as a common cathode between the OPV and top DSSC cell. On top, an anode electrode is deposited. The use of a transparent cathode and substrate allows the illumination of the threes cells from the bottom side. In addition, it is possible to fabricate an inverted version of this hybrid tandem. The bottom cathode is fabricated on top of a non transparent substrate. The three sub-cells are then fabricated in the same order as earlier with the corresponding CNT interconnecting layers. Finally, a top transparent anode is fabricated to allow for illumination of the hybrid tandem from the top (FIG. 6A).

In FIG. 7A, a variation of the triple parallel hybrid tandem is shown. A transparent substrate is used to fabricate the device. A transparent anode (made of transparent conductive oxide such as ITO) is deposited on a substrate followed by an inorganic solar cell (such as Si, CdTe, CIGS or other inorganic semiconductor). A CNT sheet is applied to form a common cathode with the middle OPV sub-cell. The CNT sheet may placed between appropriate inversion layers. A second CNT interlayer is deposited as a common anode between the OPV and top DSSC cells. On top, a cathode electrode is deposited. The use of transparent anode and substrate allows the illumination of the threes cells from the bottom side. In addition, it is possible to fabricate an inverted version of this hybrid tandem. The bottom anode (such as Au) is fabricated on top of a non transparent substrate. The three sub-cells are then fabricated in the same order as earlier with the corresponding CNT interconnecting layers. Finally, a top transparent cathode is fabricated to allow for illumination of the hybrid tandem from the top (FIG. 7B).

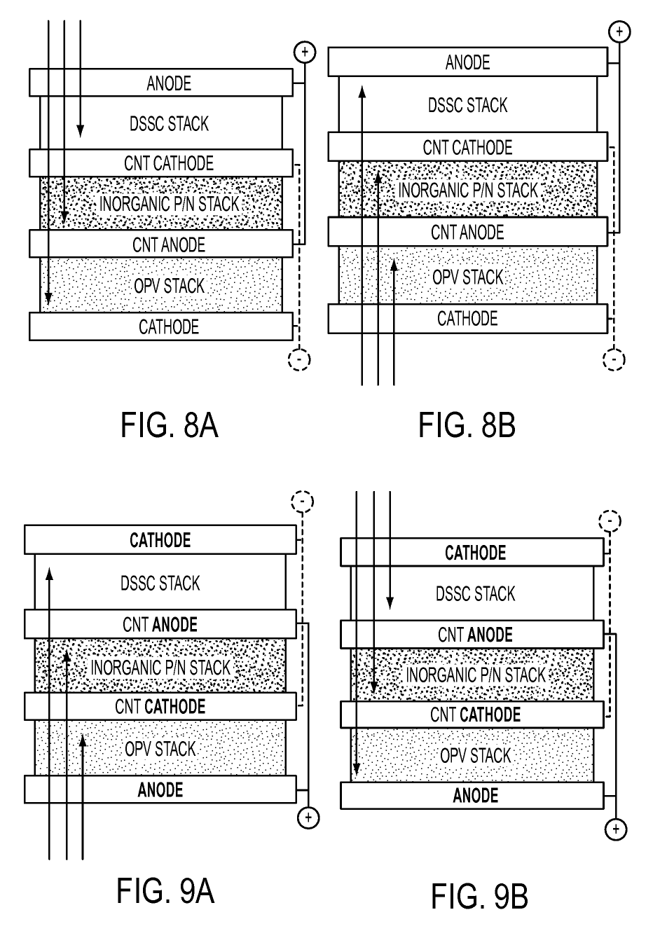

In FIG. 8B, a triple parallel hybrid tandem with different types of cells is shown. A transparent cathode (such as an inverted layer of ITO with ZnO) is deposited on a substrate followed by an organic OPV solar cell. The OPV cell may be solution processed and have acceptor—donor materials forming bilayers or bulk heterojunctions of P3HT:PCBM or PCPDTBT:PCBM. In addition, the cell can be fabricated by vapor deposition (consisted of multilayers such as CuPc:C60 and ZnPc:C60). A CNT sheet is applied to form a common anode with the middle inorganic solar cell (such as Si, CdTe, CIGS or other inorganic semiconductor). A second CNT interlayer is deposited as a common cathode between the inorganic and top DSSC cells. On top, an anode electrode is deposited. The use of transparent cathode and substrate allows for the illumination of the three cells from the bottom side. In addition, it is possible to fabricate an inverted version of this hybrid tandem. The bottom cathode in fabricated on top of a non transparent substrate. The three sub-cells are then fabricated in the same order as earlier with the corresponding CNT interconnecting layers. Finally, a top transparent anode is fabricated to allow illumination of the hybrid tandem from the top (FIG. 8A).

In FIG. 9A, a variation of the triple parallel hybrid tandem is shown. A transparent substrate is used to fabricate the device. A transparent anode (made of transparent conductive oxide such as ITO) is deposited on a substrate followed by an organic OPV solar cell. The OPV cell may be solution processed and have acceptor—donor materials forming bilayers or bulk heterojunctions of P3HT:PCBM or PCPDTBT:PCBM. In addition, the cell can be fabricated by vapor deposition (consisted of multilayers such as CuPc:C60 and ZnPc:C60). A CNT sheet is applied to form a common cathode with the middle inorganic solar cell (such as Si, CdTe, CIGS or other inorganic semiconductor). A second CNT interlayer is deposited as a common anode between the inorganic and top DSSC cells. On top, a cathode electrode is deposited. The use of transparent anode and substrate allows for the illumination of the three cells from the bottom side. In addition, it is possible to fabricate an inverted version of this hybrid tandem. The bottom anode (such as Au) is fabricated on top of a non transparent substrate. The three sub-cells are then fabricated in the same order as earlier with the corresponding CNT interconnecting layers. Finally, a top transparent cathode is fabricated to allow illumination of the hybrid tandem from the top (FIG. 9B).

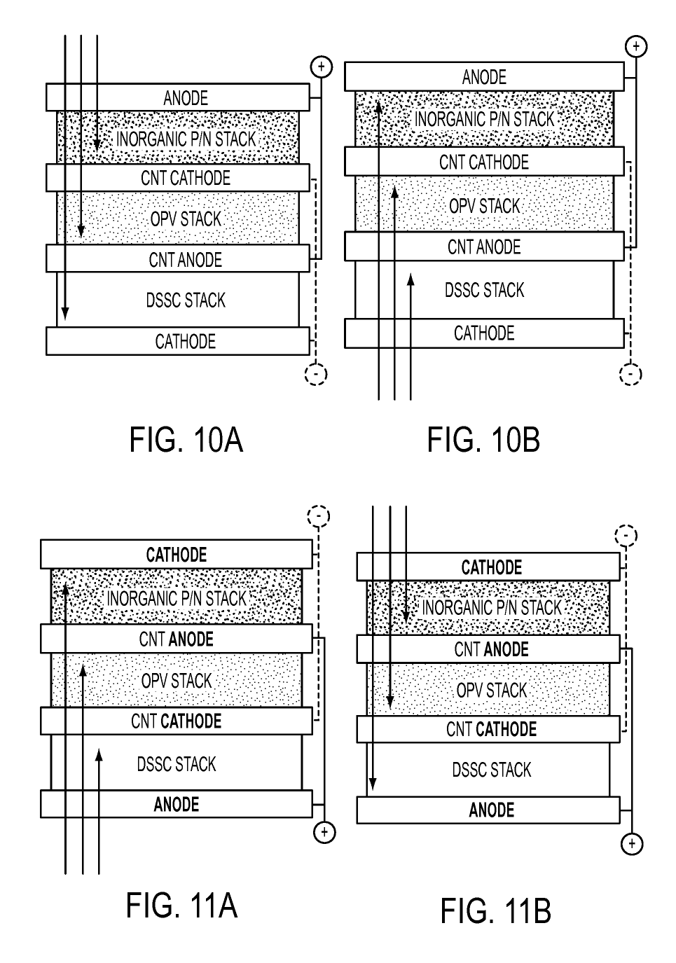

In FIG. 10B, a triple parallel hybrid tandem with different types of cells is shown. A transparent cathode is deposited on a substrate followed by an organic DSSC solar cell. A CNT sheet is applied to form a common anode with the middle OPV cell. The OPV cell may be solution processed and have acceptor—donor materials forming bilayers or bulk heterojunctions of P3HT:PCBM or PCPDTBT:PCBM. In addition, the cell can be fabricated by vapor deposition (consisted of multilayers such as CuPc:C60 and ZnPc:C60). A second CNT interlayer is deposited as a common cathode between the OPV and top inorganic cells. On top, an anode electrode is deposited. The use of transparent cathode and substrate allows for the illumination of the three cells from the bottom side. In addition, it is possible to fabricate an inverted version of this hybrid tandem. The bottom cathode in fabricated on top of a non transparent substrate. The three sub-cells are then fabricated in the same order as earlier with the corresponding CNT interconnecting layers. Finally, a top transparent anode is fabricated to allow illumination of the hybrid tandem from the top (FIG. 10A).

In FIG. 11A, a variation of the triple parallel hybrid tandem is shown. A transparent substrate is used to fabricate the device. A transparent anode (made of transparent conductive oxide such as ITO) is deposited on a substrate followed by a DSSC. A CNT sheet is applied to form a common cathode with the middle OPV cell. A second CNT interlayer is deposited as a common anode between the OPV and top inorganic cells. On top, a cathode electrode is deposited. The use of a transparent anode and substrate allows the for illumination of the three cells from the bottom side. In addition, it is possible to fabricate an inverted version of this hybrid tandem. The bottom anode is fabricated on top of a non transparent substrate. The three sub-cells are then fabricated in the same order as earlier with the corresponding CNT interconnecting layers. Finally, a top transparent cathode is fabricated to allow illumination of the hybrid tandem from the top (FIG. 11B).

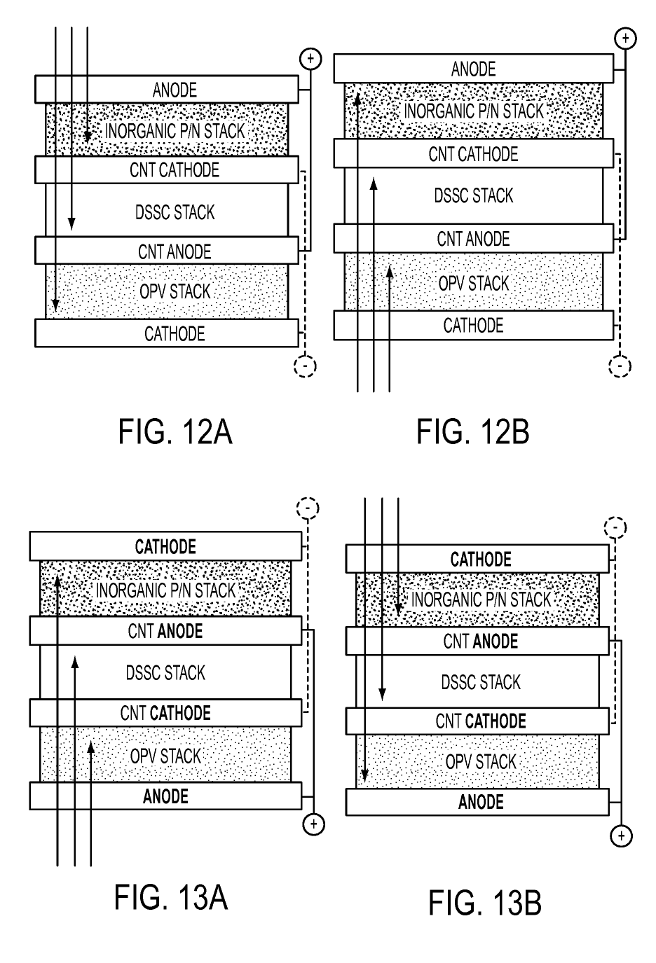

In FIG. 12B, a triple parallel hybrid tandem with different types of cells is shown. A transparent cathode is deposited on a substrate followed by an OPV solar cell. A CNT sheet is applied to form a common anode with the middle DSSC cell. A second CNT interlayer is deposited as a common cathode between the DSSC and top inorganic cells. On top, an anode electrode is deposited. The use of a transparent cathode and substrate allows the illumination of the three cells from the bottom side. In addition, it is possible to fabricate an inverted version of this hybrid tandem. The bottom cathode in fabricated on top of a non transparent substrate. The three sub-cells are then fabricated in the same order as earlier with the corresponding CNT interconnecting layers. Finally, a top transparent anode is fabricated to allow illumination of the hybrid tandem from the top (FIG. 12A).

In FIG. 13A, a variation of the triple parallel hybrid tandem is shown. A transparent substrate is used to fabricate the device. A transparent anode is deposited on a substrate followed by an OPV solar cell. A CNT sheet is applied to form a common cathode with the middle DSSC cell. A second CNT interlayer is deposited as a common anode between the DSSC and top inorganic cells. On top, a cathode electrode is deposited. The use of a transparent anode and substrate allows for the illumination of the three cells from the bottom side. In addition, it is possible to fabricate an inverted version of this hybrid tandem. The bottom anode is fabricated on top of a non transparent substrate. The three sub-cells are then fabricated in the same order as earlier with the corresponding CNT interconnecting layers. Finally, a top transparent cathode is fabricated to allow illumination of the hybrid tandem from the top (FIG. 13B).

Because of the different nature and different origin of solar cells participating in multi junction parallel tandem—the nature of interfaces is most important. In the case of a tandem or multi junction between inorganic solar cells of the same nature the interface is also an inorganic interface. It is easy to handle, it is well known that over doping the junction layers (p++/n++) creates a recombination junction for in series connectivity. However, if the origin of material needed to be connected to each is very different, then the interface properties are the most critical for device operation. So, the combination of very brutal, mechanically strong inorganic materials with something very soft, for example polymeric organic materials, or the jelly electrolyte of the DSSC requires special handling. Therefore, the use of special carbon nanotube or carbon nano ribbons, or other nanomaterials, that are highly porous and act like a sponge. They stay in between that interface and functionalize itself from both sides (one side inorganic side and other organic or both sides organic). The below examples describe details to emphasize the special nature of interconnectivity required for interfacial functionalization.

### WORKING EXAMPLES

### Example 1

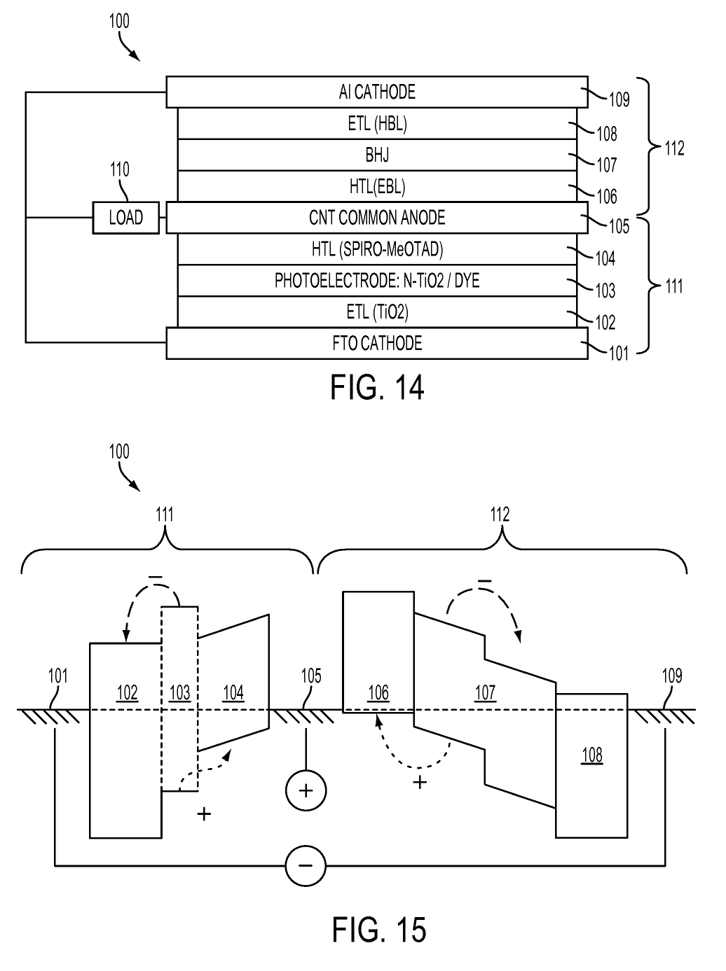

FIG. 14 illustrates a hybrid tandem structure between a Solid State Dye Sensitized Solar Cell (SS-DSSC) sub cell (111) and a bulk heterojunction organic photovoltaic (OPV) sub-cell (112) connected in parallel through common anode (105). SS-DSSC sub-cell (111) comprises of a transparent conductive oxide (TCO) cathode (101) such as FTO, deposited onto a transparent substrate such glass, plastic or polymer. A transparent electron transport layer (ETL) (102) such as TiO₂ is then deposited from solution using compatible processing techniques such as spin coating, slot dye coating or doctor blading. On top of ETL (102) a photo electrode (103) is created from solution using compatible processing techniques such those used for ETL (102). The photoelectrode (103) consists of a nanoporous layer, such as nanoporous TiO2 which has been sensitized by a photoactive dye, such as Indoline Dye. On top of the sensitized photoactive layer (103) a hole transport layer (HTL) (104) such as Spiro-MeOTAD is deposited from solution using compatible processing techniques. During the deposition of HTL (104) some of the HTL will infiltrate the nanoporous photoactive layer to create a composite photoactive layer (103) comprising of nanoporous TiO2, Inodine Dye, and Spiro-MeOTAD. On top of HTL (104) a transparent anode (105) is deposited to create a complete sub-cell (111).

The transparent anode (105) can be either single wall or multiwall carbon nanotubes. Anode (105) must be highly conductive as well as optically transparent, for these reasons carbon nanotubes are favorable. When electrically conductive nanotubes are sandwiched between two HTL layers, (104) and (105) the electrode will function as an anode and collect holes.

OPV sub-cell (112) comprises of a hole transport layer (HTL) (106) such as MoO₃, V2O5, PEDOT:PSS deposited using thermal deposition in the case of MoO₃ and V₂O₅ or can be spin coated in the case of PEDOT:PSS on the top of the device stack comprising of sub-cell (111) and transparent common anode (105). Bulk heterojunction layer (107) comprising of a mixture of electron donating organic semi conducting material such as P3HT, PCPDTBT, MEH-PPV and acceptor fullerene such as C60, C70 or chemically modified acceptor fullerene such as PC₆₁BM or PC₇₁BM is deposited on the top of sub-cell stack (111), common anode (105) and HTL (106) to form the photoactive component of sub-cell (112). Electron transport layer (108) can be optionally deposited on top of bulk heterojunction layer (107) prior to thermal evaporation of top cathode (109) completing sub-cell (112) and completing a parallel tandem device (100) consisting of SS-DSSC sub-cell (111) and OPV sub-cell (112) electrically connected in parallel using common anode (105).

FIG. 15 illustrates schematically the hybrid tandem between a SS-DSSC sub-cell (111) and OPV sub-cell (112) connected in parallel through a common anode (105) operating under illumination at short circuit conditions. Cathodes (101) and (109) as well as common anode (105) have equilibrated to the Fermi level represented as the dashed line. During illumination light passes through the substrate, TCO (101), and the ETL (102) of the SS-DSSC sub-cell (111) before it is absorbed on the dye molecule (103) within the photoelectrode (FIG. 14 103). The excited dye molecule will transfer its electron to the nanoporous material within the photoelectrode (FIG. 14 103) and eventually transfer that electron to the ETL (102) to be used as electrical current once it is collected at the TCO of the cathode (101). The hole which was generated on the excited dye molecule (103) will be transferred to the HTL (104) and will be collected at the common anode (105). The light which was not absorbed by the photoelectrode of sub-cell (111) will pass through the HTL (106) of the OPV sub-cell (112) and be absorbed within the photo active layer (107) creating an exciton on the donor material, this exciton will be separated into an electron on the acceptor and a hole on the polymer. Under the influence of the electric field generated by the common anode (105) and cathode (109) the charges will move to the respective transport materials, holes to HTL (106) and electrons to ETL (108). Holes will be collected on the common anode (105) and electrons on the cathode (109) of the OPV sub-cell (112).

### Example 2

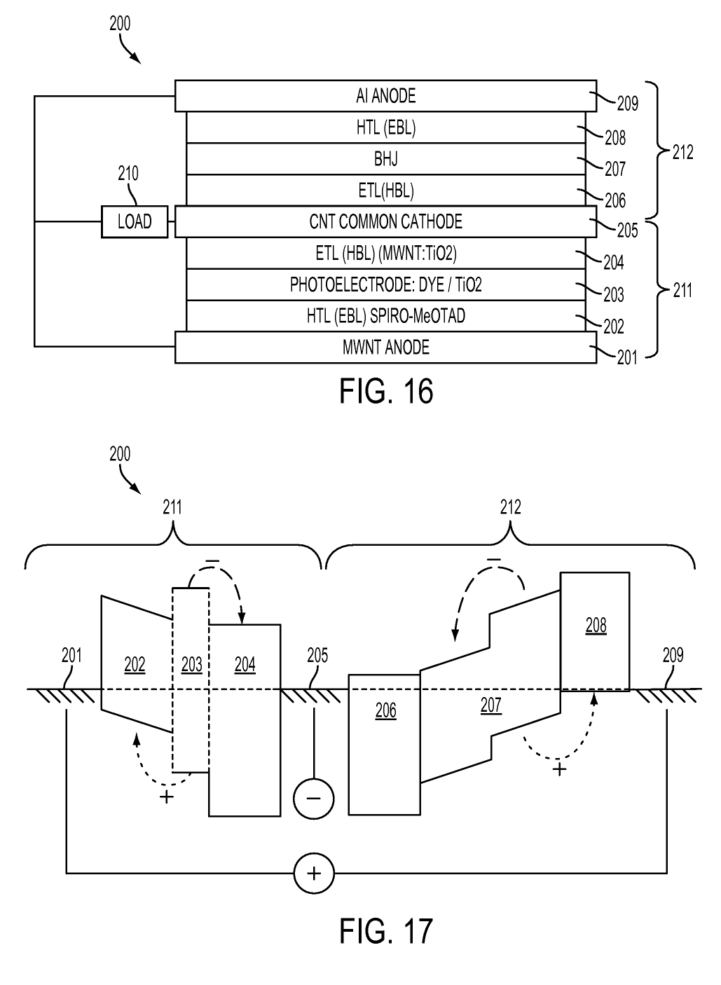

FIG. 16 illustrates the inverted hybrid tandem architecture of FIG. 14 between a Solid State Dye Sensitized Solar Cell (SS-DSSC) sub-cell (211) and a bulk heterojunction organic photovoltaic (OPV) sub-cell (212) connected in parallel through common cathode (205). SS-DSSC sub-cell (211) comprises of a transparent anode (201), such as single wall or multi wall carbon nanotubes on top of a transparent substrate such glass, plastic or polymer. A transparent hole transport layer (HTL) (202) such as Spiro-MeOTAD which is deposited from solution using compatible processing techniques such as spin coating, slot dye coating or doctor blading. On top of HTL (202) a photoelectrode (203) is created using carbon nanotubes (single or multiwall) that have been infiltrated using the biscrolling and birolling techniques developed at the University of Texas at Dallas. The biscrolled or birolled nanotubes are done so such that TiO₂ nanoparticles are within the matrix of nanotubes. This biscrolled or birolled matrix composite consisting of a interpenetrating nanotube network and TiO₂ nanoparticles is then sensitized in a dye, such as Indoline Dye. A Nanoporous TiO₂ layer cannot be used in this inverted SS-DSSC architecture because of the high sintering temperatures required to achieve the favorable anatase crystalline phase. In this Nanotube:Ti0₂:Dye composite, the nanotubes provide the continuous electrical pathways for charges originally provided by the TiO₂ in the traditional DSSC stack as described in the previous example. The TiO₂ within the composite allows for nucleation sites where the Dye molecule can attach itself, in this way there is no need to redesign or functionalize the nanotubes. On top of the photoelectrode (203) an electron transport layer (ETL) (204) is deposited consisting of carbon nanotubes which have been treated with TiO₂. TiO₂ treatment is done preferentially so that the layer that is at the interface with photoelectrode (203) contains a high concentration of TiO₂ nanoparticles while the side which is not treated can function as the common cathode (205) for the parallel cell (200) and the cathode for sub-cell (211).

The transparent cathode (205) can be either single wall or multiwall carbon nanotubes. Cathode (205) must be highly conductive as well as optically transparent, for these reasons carbon nanotubes are favorable. When electrically conductive nanotubes are sandwiched between two ETL layers, (204) and (205) the electrode will function as an cathode and collect electrons.

OPV sub-cell (212) comprises of a electron transport layer (ETL) (206) such as ZnO, TiO2, WO3 deposited using thermal deposition or can be spin coated from nanoparticle or sol-gel solutions on the top of the device stack comprising of sub-cell (211) and transparent common cathode (205). Bulk heterojunction layer (207) comprising of a mixture of electron donating organic semi conducting material such as P3HT, PCPDTBT, MEH-PPV and acceptor fullerene such as C60, C70 or chemically modified acceptor fullerene such as PC61BM or PC71BM is deposited on the top of sub-cell stack (211), common cathode (205) and ETL (206) to form the photoactive component of sub-cell (212). Hole transport layer (208) can be optionally deposited using thermal deposition or solution processing techniques on top of bulk heterojunction layer (207) prior to thermal evaporation of top anode (209) completing sub-cell (212) and completing a parallel tandem device (200) consisting of SS-DSSC sub-cell (211) and OPV sub-cell (212) electrically connected in parallel using common cathode (205).

FIG. 17 illustrates schematically the hybrid tandem between an inverted SS-DSSC sub-cell (211) and OPV sub-cell (212) connected in parallel through a common cathode (205) operating under illumination at short circuit conditions. Anodes (201) and (209) as well as common cathode (205) have equilibrated to the Fermi level represented as the dashed line. During illumination light passes through the substrate, transparent anode (201), and the HTL (202) of the SS-DSSC sub-cell (211) before it is absorbed on the dye molecule (203) within the photoelectrode (FIG. 16 203). The excited dye molecule will transfer its electron to the TiO2 nanoparticle within the photoelectrode (FIG. 16 203) and eventually transfer that electron to the continuous nanotube network and then to the ETL (204) to be used as electrical current once it is collected at common cathode (205). The hole which was generated on the excited dye molecule (203) will be transferred to the HTL (202) and will be collected at the transparent anode (201). The light which was not absorbed by the photoelectrode of sub-cell (211) will pass through the ETL (206) of the OPV sub-cell (212) and be absorbed within the photo active layer (207) creating an exciton on the donor material, this exciton will be separated into an electron on the acceptor and a hole on the polymer. Under the influence of the electric field generated by the common cathode (205) and anode (209) the charges will move to the respective transport materials, holes to HTL (208) and electrons to ETL (206). Electrons will be collected on the common cathode (505) and holes on the anode (209) of the OPV sub-cell (212).

### Example 3

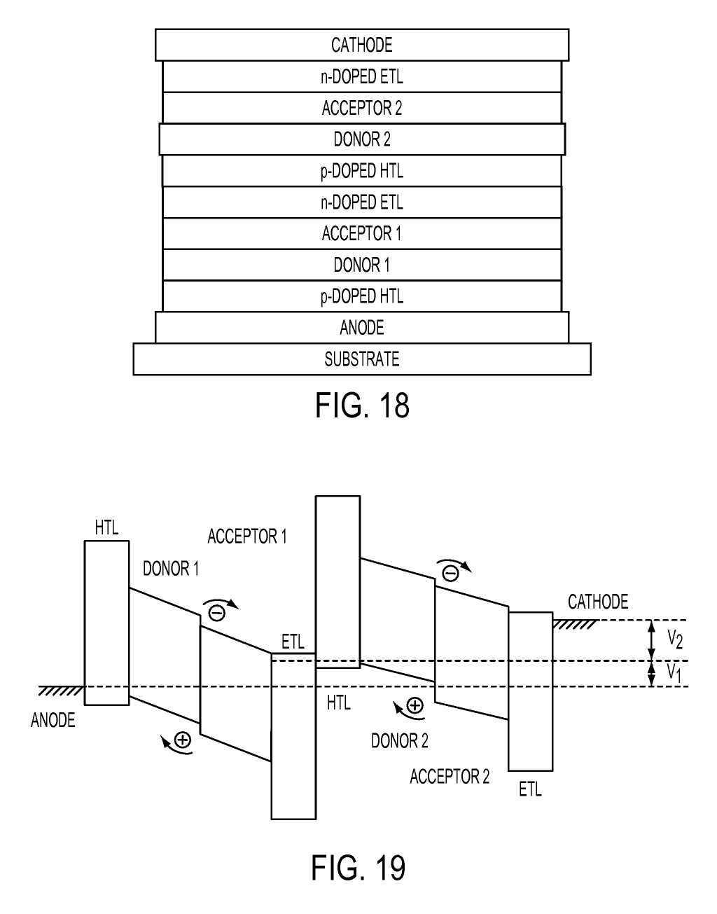

FIG. 18 illustrates a solar cell utilizing doped transport layers and spectrally different donor materials connected in series from two sub-cells. The first sub-cell is built on top of the transparent SUBSTRATE which has a transparent ANODE which can be made of various transparent oxides (TCO) such as Indium Tin Oxide (ITO), Fluorinated Tin Oxide (FTO), doped Zinc Oxide (ZnO) or highly doped conducting polymers such as PEDOT:PSS or conducting nanomaterials such as single wall and multi wall carbon nanotubes. A p-DOPED HTL is deposited on top of the transparent anode, the hole transport material can be an organo-metallic or organic molecule such as NPB, TPD, Meo-TPD, TFB, mTDATA and others which can be doped by F4-TCNQ or other dopants by thermal sublimation and co evaporation techniques, other HTLs can also be used such as PEDOT which can be polymerized forming PEDOT and doped by an acid such as PSS which can be dispersed in solution and processed by compatible techniques such as doctor blading, slot coating or spin coating, other HTLs can also be used such as semiconducting organic polymers doped through the use of a self assembled monolayer (SAM) or through the use of electrochemical charging with ionic liquid species. p-DOPED HTLs have the unique quality where the Fermi level is much closer to the highest occupied molecular orbital (HOMO). Using processing compatible techniques DONOR1 and ACCEPTOR1 can be deposited on the top of p-DOPED HTL, donor materials can be semiconducting organo-metallic or organic molecules such as CuPc, ZnPc and others or semiconducting polymeric materials P3HT, PCPDTBT, PPV coupled with compatible acceptor molecules such as C₆₀,C₇₀, PCBM processed using compatible techniques such as thermal evaporation or solution processing. DONOR1 and ACCEPTOR1 can be processed to create a strong interface or a gradient using thermal evaporation or thermal coevaporation in the case of organo-metallic or organic molecules and solution processed from pristine or blended solutions in the case of organic polymeric materials. A gradient can be formed when the coevaporation rates of the DONOR1 and ACCEPTOR1 material are changed as the layer thickness is changed creating a donor rich region near the p-DOPED HTL and an acceptor rich region near the n-DOPED ETL region. The n-DOPED ETL is deposited from compatible processing techniques, such as thermal sublimation evaporation of ETL materials C60, Bphen, Alg₃ and others with co evaporation of n-type dopants such as list of LiF, CsF, Cs₂CO₃ , Acridine Orange Base, CoCp₂. This n-DOPED ETL layer will complete the first sub-cell of the tandem cell connected in series.

The second sub-cell is built on top of the first sub-cell, beginning with a p-DOPED HTL which can be the same or different than the p-DOPED HTL of the first sub-cell using the same techniques described for the first sub-cell. On top of p-DOPED HTL the photoactive materials, DONOR2 and ACCEPTOR2 are deposited using process compatible techniques as described for the first sub-cell . The photoactive donor material, DONOR2, is chosen to enhance the spectral coverage of the overall tandem cell and best match photocurrent generated due to the limitations on overall current collection of the cells connected in series. An n-DOPED ETL layer is deposited on top of the second sub-cells photoactive layer, DONOR2 and ACCEPTOR2, using processing techniques and materials described for the first sub-cell and lastly a Cathode, using low work function metals such as Ca, Mg, Li, Al, Ag or any alloy of these materials is deposited completing the second sub-cell and the total tandem in series connection. The layers connecting the first sub-cell and the second, n-DOPED ETL and p-DOPED HTL, function as the recombination site for the tandem cell. Electrons generated within the first sub-cell's photoactive layer, DONOR1 and ACCEPTOR1, will travel through the n-DOPED ETL of the first sub-cell and recombine with holes generated within the second sub-cell's photoactive layer, DONOR2 and ACCEPTOR2, which have been transferred through the second sub-cells p-DOPED HTL, at the interface.

FIG. 19 illustrates schematically the series tandem between two doped sub-cells and connected in series through a recombination layer consisting of n-DOPED ETL and p-DOPED HTL operating under illumination at short circuit conditions. Incident photons pass through the transparent substrate and anode before being absorbed on DONOR1. Once absorbed on DONOR1, the excited electron is transferred to ACCEPTOR1 while the hole remains on DONOR1. Under the influence of an electric field the hole on DONOR1 will move towards the p-DOPED HTL and generate electrical current after being collect on anode. The electron will move through ACCEPTOR1 towards the n-DOPED ETL recombination site interface under the same electrical field. The light that was not absorbed within the first sub-cell will be absorbed within the photoactive layer, DONOR2 and ACCEPTOR2 of the second sub-cell. Light within the second sub-cell will be absorbed on DONOR2 creating an excited electron. The excited electron will be transferred to the acceptor, ACCEPTOR2 of the second sub-cell. Under the influence of the electric field, electrons on ACCEPTOR2 will travel to the n-DOPED ETL and be collected as electrical current on the cathode. Under the same electric field the hole sitting on DONOR2 within the second sub-cell will move towards the p-DOPED HTL towards the recombination site. Electrons from the first sub-cell on the n-DOPED ETL will recombine with holes from the second sub-cell on the p-DOPED HTL.

### Example 4

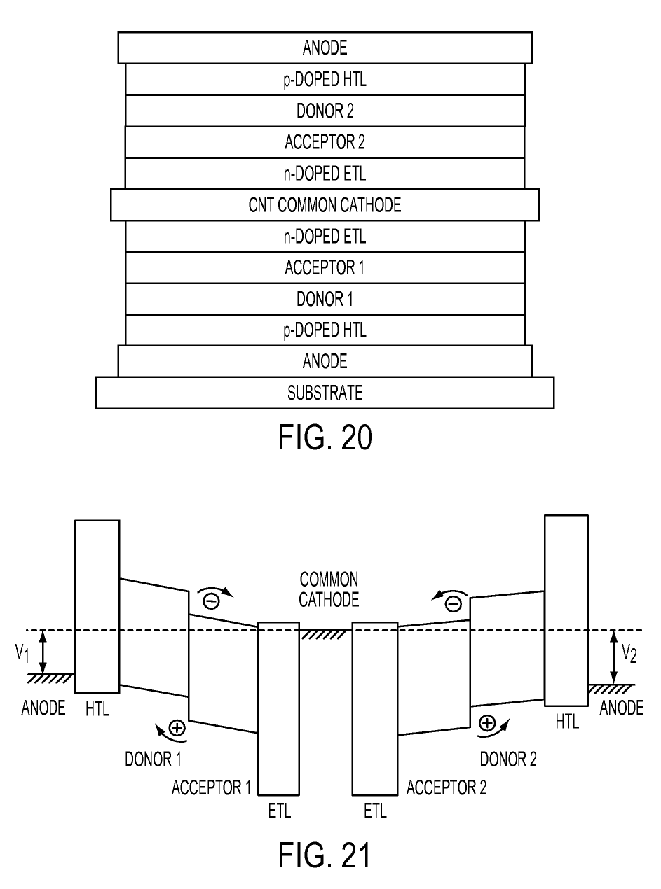

FIG. 20 illustrates a solar cell utilizing doped transport layers and spectrally complementary donor materials connected in parallel through a common cathode from two sub-cells. The first sub-cell is built on top of the transparent SUBSTRATE which has a transparent ANODE made of various transparent oxides (TCO) such as Indium Tin Oxide (ITO), Fluorinated Tin Oxide (FTO), doped Zinc Oxide (ZnO) or highly doped conducting polymers such as PEDOT:PSS or conducting nanomaterials such as single wall and multi wall carbon nanotubes. A p-DOPED HTL is deposited on top of the transparent anode, the hole transport material can be an organo-metallic or organic molecule such as NPB, TPD, Meo-TPD, TFB, mTDATA and others which can be doped by F₄-TCNQ and other by thermal sublimation and co evaporation techniques, other HTLs can also be used such as EDOT which can be polymerized forming PEDOT and doped by an acid such as PSS which can be dispersed in solution and processed by compatible techniques such as doctor blading, slot coating or spin coating, other HTLs can also be used such as semiconducting organic polymers doped through the use of a self assembled monolayer (SAM) or through the use of electrochemical charging with ionic liquid species. p-DOPED HTLs have the unique quality where the Fermi level is much closer to the highest occupied molecular orbital (HOMO). Using processing compatible techniques DONOR1 and ACCEPTOR1 materials can be deposited on the top of p-DOPED HTL, donor materials can be semiconducting organo-metallic or organic molecules such as CuPc, ZnPC and others or semiconducting polymeric materials P3HT, PCPDTBT, PPV coupled with compatible acceptor molecules (usually C60,C70,PCBM) processed using compatible techniques such as thermal evaporation or solution processing. DONOR1 and ACCEPTOR1 materials can be processed to create either a strong interface or a gradient using thermal evaporation or thermal coevaportion in the case of organo-metallic or organic molecules and solution processed from pristine or blended solutions in the case of organic polymeric materials. A gradient can be formed when the coevaporation rates of the DONOR1 and ACCEPTOR1 materials are changed as the layer thickness is changed creating a donor rich region near the p-DOPED HTL and an acceptor rich region near the n-DOPED ETL region. The n-DOPED ETL is deposited from compatible processing techniques , such as thermal sublimation evaporation of ETL materials C60, Bphen, Alq₃ and others with co evaporation of n-type dopants such as list of LiF, CsF, Cs₂CO₃, Acridine Orange Base, CoCp₂. A common cathode with low sheet resistance and high optical transparency such as single or multi walled carbon nanotubes is deposited on the top of the first sub-cells n-DOPED ETL. This common cathode will complete the first semi cell of the tandem cell connected in parallel as well as begin the second sub-cell.

The second sub-cell is built on top of the first sub-cell, which includes the common cathode followed by an n-DOPED HTL which can be the same or different than the n-DOPED HTL of the first sub-cell using the same techniques described for the first sub-cell. On top of n-DOPED HTL the photoactive materials, DONOR2 and ACCEPTOR2 are deposited using process compatible techniques as described for the first sub-cell. The photoactive donor material, DONOR2, is chosen to enhance the spectral coverage of the overall tandem cell and best match the open circuit voltage of the first sub-cell while generating a large amount of photo current. A p-DOPED HTL layer is deposited on top of the second sub-cell's photoactive layer, DONOR2 and ACCEPTOR2, using processing techniques and materials described for the first sub-cell and lastly an anode , using high work function metals such as Au or Pt or any alloy of these materials is deposited completing the second sub-cell and the total tandem in parallel connection.

The layers that compose the second sub-cell must be inverted so that the top electrode will be an anode, while the inner common electrode functions only as a common cathode. Electrons generated within the first sub-cell's photoactive layer, DONOR1 and ACCEPTOR1, will travel through the n-DOPED ETL of the first sub-cell and be collected on the common anode with the electrons that are generated within the second sub-cell's photoactive layer, DONOR2 and ACCEPTOR2. This will lead to an overall increase in the photocurrent generated by the tandem cell.

FIG. 21 illustrates schematically the tandem between two doped sub-cells and connected in parallel through a common cathode composed of single or multi walled carbon nanotubes operating under illumination at short circuit conditions. Incident photons pass through the transparent substrate and anode before being absorbed on DONOR1. Once absorbed on DONOR1, the excited electron is transferred to ACCEPTOR1 while the hole remains on DONOR1. Under the influence of an electric field the hole on DONOR1 will move towards the p-DOPED HTL and generate electrical current after being collect on anode. The electron will move through ACCEPTOR1 towards the n-DOPED ETL and eventually to the common cathode under the same electrical field. The light that was not absorbed within the first sub-cell will be absorbed within the photoactive layer, DONOR2 and ACCEPTOR2 of the second sub-cell. Light within the second sub-cell will be absorbed on DONOR2 creating an excited electron. The excited electron will be transferred to the acceptor, ACCEPTOR2 of the second sub-cell. Under the influence of the electric field, electrons on ACCEPTOR2 will travel to the n-DOPED ETL and be collected as electrical current on the common cathode. Under the same electric field the hole sitting on DONOR2 within the second sub-cell will move towards the p-DOPED HTL towards the anode of the second sub-cell. Electrons from both the first and second sub-cells will be collected on the common cathode and generate electrical current equal to the sum of the total currents of each sub-cell.

### Example 5

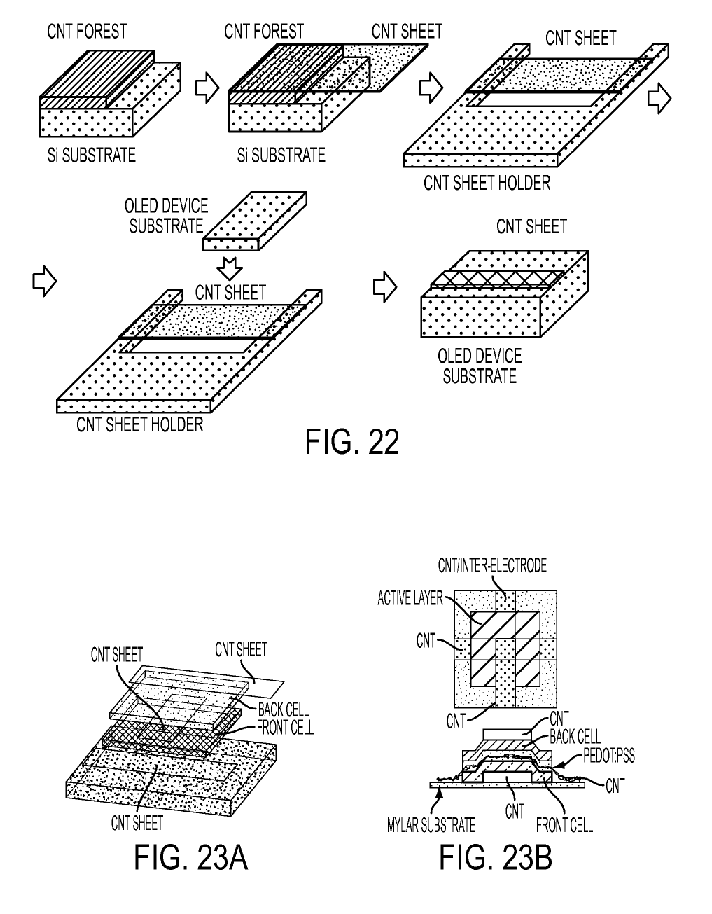

The process of dry-drawing of CNT sheets has been discovered by scientists at the Nanotech Institute of The University of Texas at Dallas and has been improved further by several groups, including those who emphasize the drawing of CNT yarns and fibers. Synthesis of CNT is done inside a three zone furnace with two inch diameter quartz tube will be utilized for Chemical Vapor Deposition (CVD) of CNT. Acetylene gas is inserted in a reactor at about 700 C during the growth process. This CVD furnace will grow multi-walled carbon nanotubes (MWCNT) on the silicon wafer with iron catalyst deposited by e-beam deposition. After the CNT forest is grown on the silicon wafer, the forest can be pulled out and transferred as free standing CNT sheets. A CNT forest grown on the surface of a Si substrate is shown FIG. 22. A CNT sheet is then pulled off the forest and a continuous strand is formed. The CNT sheet it placed free standing on the CNT sheet holder as for storage and transfer to any surface. The CNT sheet may then easily be laminated on top of the OLED device bare substrate or on top of any layer that is part of an OLED structure. FIG. 3A shows a photograph of CNT forest and the process of pulling a CNT sheet.

### Example 6

In FIG. 23A we illustrate the parallel tandem architecture of a device consisted with two OPV sub-cells. On the surface of the substrate we deposit the first electrode. Transparent conductive oxides (TCO), such as ITO are very commonly used as bottom electrodes in OPV devices, but CNT sheets and other nano materials (such as graphene, graphene oxide and others) can also be used. On top of the bottom electrode the first cell is deposited. The first cell may be made of any donor—acceptor material pair that can be processed from solution (such as P3HT, PPV type, PCPDTBT and PCBM) or vacuum deposition (such as ZnPc, CuPc and C60). The interlayer is fabricated of another CNT sheet. It can be functionalized with additional inversion layers and is deposited between the two sub cells. The top sub-cell can be consist of the same or different donor-acceptor material pair as the bottom one. The use of a different pair is preferred to achieve wider light absorption. On the top a second electrode is placed that can be one more CNT sheet or other metal with appropriate work function. FIG. 23B shows side and top views of the vertically stacked OPV sub-cells and the geometry of the resulting three electrode parallel tandem solar cell.

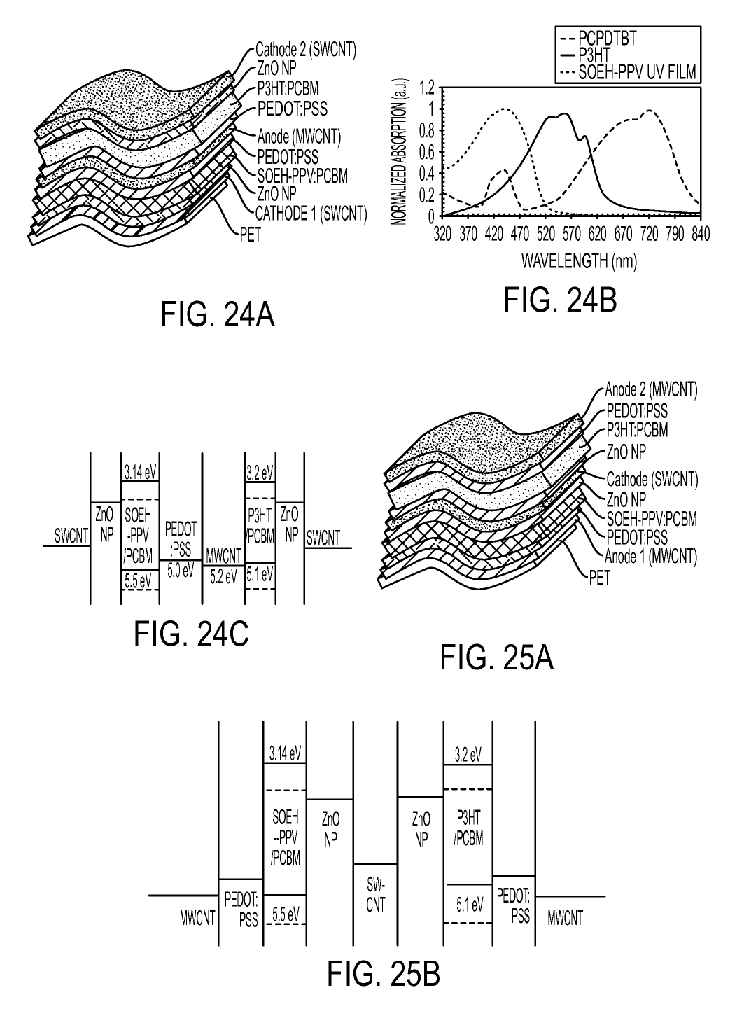

The detailed structure of this type of parallel tandem cell is presented in FIG. 24A. An advantage of CNT sheets over traditional TCOs is in the integration with flexible substrates. The flexible parallel tandem solar cell shown in this figure uses a single wall CNT sheet (SWCNT) as bottom cathode that is inverted with an additional layer on ZnO nanoparticles to facilitate electron extraction. The bottom sub cell donor-acceptor pair consists of SOEH-PPV:PCBM blend. A layer of PEDOT:PSS is spin coated as electron blocking layer prior to fabrication of the interlayer. Other materials as MoO₃ may be used instead of PEDOT:PSS. Multi wall CNT sheets are used as the interlayer and are transferred on top the layer stack from free-standing state with our proprietary dry process. On the top of the interlayer an additional layer of PEDOT:PSS planarizes the surface and is the electron blocking layer of top sub-cell. The top sub cell's absorption layer is made of the widely known P3HT:PCBM blend. The second (top) cathode is deposited usually by thermal evaporation of low work function material (such as LiF, CsF, Ca and others) and a metal (such Al, Ag, etc) through a shadow mask. Additionally, a second SWCNT sheet can be used with ZnO (or other low work-function material) inversion layer to form the top cathode. FIG. 24B shows the of PCPDTBT, P3HT, and SOEH-PPV materials that are used as donor materials in parallel tandem OPVs. The choice of complimentary materials results in harvesting of wider regions of the solar radiation spectrum.

The band diagram of the tandem device is shown in FIG. 24C. Under illumination light passes through the substrate and bottom transparent cathode and is absorbed within the photo active layer of SOEH-PPV:PCBM creating an exciton on the donor material, this exciton will be separated into an electron on the acceptor and a hole on the polymer. Under the influence of the electric field generated by the common anode and bottom cathode the charges will move towards and collected to the respective electrodes, holes to common anode and electrons to bottom cathode. At the same time, light passes through the bottom semitransparent cell and interlayer. It is absorbed within the photo active layer of P3HT:PCBM creating an exciton on the donor material, this exciton will be separated into an electron on the acceptor and a hole on the polymer. Under the influence of the electric field generated by the common anode and top cathode the charges will move towards and collected to the respective electrodes, holes to common anode and electrons to top cathode.

### Example 7

In FIG. 25A, we illustrate the parallel tandem architecture of a device consisting of with two OPV sub-cells that connected in parallel with a common cathode interlayer. The flexible parallel tandem solar cell shown in this figure uses a MWCNT sheet bottom anode. A layer of PEDOT:PSS is deposited by spin coating to planarize the surface. The bottom sub cell donor-acceptor pair is consisted of SOEH-PPV:PCBM blend. A sheet of SWCNTs is used as the interlayer and are transferred on top the layer stack from free-standing state with our proprietary dry process. It is important for the tandem cell operation the addition of ZnO nanoparticle layers to facilitate electron extraction from the two subcell towards the interlayer. The top sub cell's absorption layer is made of the widely known P3HT:PCBM blend. The second (top) anode is deposited usually by thermal evaporation of high work function materials (such as MoO₃, Au, Pt and others through a shadow mask. Additionally, a second MWCNT sheet can be used with MoO₃ layer.

The band diagram of the tandem device is shown in FIG. 25B. Under illumination light passes through the substrate and bottom transparent anode and is absorbed within the photo active layer of SOEH-PPV:PCBM creating an exciton on the donor material, this exciton will be separated into an electron on the acceptor and a hole on the polymer. Under the influence of the electric field generated by the common cathode and bottom anode the charges will move towards and collected to the respective electrodes, holes to common cathode and electrons to bottom anode. At the same time, light passes through the bottom semitransparent cell and interlayer. It is absorbed within the photo active layer of P3HT:PCBM creating an exciton on the donor material, this exciton will be separated into an electron on the acceptor and a hole on the polymer. Under the influence of the electric field generated by the common cathode and top anode the charges will move towards and collected to the respective electrodes, holes to common cathode and electrons to top anode.

### Example 8

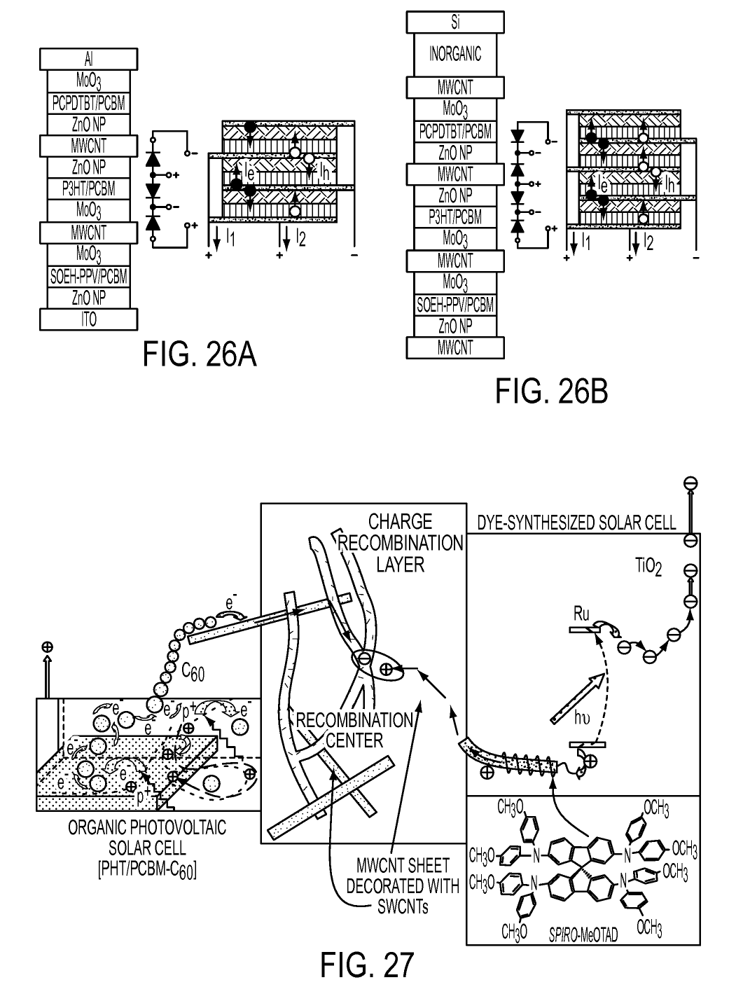

The parallel tandem of our invention can be extended from the two unit subcell described in examples 6 and 7 to multi-unit tandems. The detailed structure of a three unit parallel tandem cell is presented in FIG. 26A. The parallel tandem solar cell shown in this figure uses an ITO layer as bottom cathode that is inverted with an additional layer on ZnO nanoparticles to facilitate electron extraction. The bottom sub cell donor-acceptor pair is consisted of SOEH-PPV:PCBM blend. A layer of MoO₃ is spin coated as electron blocking layer prior to fabrication of the interlayer. Multi wall CNT sheets are used as the interlayer and are transferred on top the layer stack from free-standing state with our proprietary dry process. On the top of the interlayer an additional layer of MoO₃ assists in planarization of the surface and hole collection from of middle sub-cell. The middle sub cell's absorption layer is made of P3HT:PCBM blend. The second interlayer is fabricated by deposition of a second MWCNT sheet. It is important for the tandem cell operation and common cathode (2^{nd} interlayer) the addition of ZnO nanoparticle layers to facilitate electron extraction from the top and middle subcell towards the interlayer. The top sub cell donor-acceptor pair is consisted of PCPDTBT:PCBM blend. The absorption of PCPDTBT is complimentary to the first two donor materials (FIG. 24B) that results harvesting of a wide region of the solar radiation spectrum. The top anode is fabricated by thermal evaporation of a bilayer of MoO₃ and Al.

The above three unit architecture may be further combined with an inorganic solar cell. The detailed structure of a four unit hybrid parallel tandem cell with a top inorganic is presented in FIG. 26B. The hybrid parallel tandem solar cell shown in this figure uses an ITO layer as bottom cathode that is inverted with an additional layer on ZnO nanoparticles to facilitate electron extraction. The bottom sub cell donor-acceptor pair is consisted of SOEH-PPV:PCBM blend. A layer of MoO₃ is spin coated as electron blocking layer prior to fabrication of the interlayer. Multi wall CNT sheets are used as the interlayer and are transferred on top the layer stack from free-standing state with our proprietary dry process. On the top of the interlayer an additional layer of MoO₃ assists in planarization of the surface and hole collection from of middle sub-cell. The second sub cell's absorption layer is made of P3HT:PCBM blend. The second interlayer is fabricated by deposition of a second MWCNT sheet. It is important for the tandem cell operation and common cathode (2^{nd} interlayer) the addition of ZnO nanoparticle layers to facilitate electron extraction from the top and middle subcell towards the interlayer. The top sub cell donor-acceptor pair consists of PCPDTBT:PCBM blend. The absorption of PCPDTBT is complimentary to the first two donor materials (FIG. 24B) that results harvesting of a wide region of the solar radiation spectrum. In this architecture a third interlayer is needed between the top OPV cell and inorganic. The interlayer is consisted of a layer of MoO₃ and MWCNT sheets as common anode. Finally, an inorganic cell (such as Si, CdTe, CIGS or other inorganic semiconductor) is fabricated as top unit of the hybrid parallel tandem.

### Example 9

FIG. 27 illustrates a hybrid tandem solar cell between an organic photovoltaic cell comprised of a bulk heterojunction layer with poly(3-hexylthiophene) and chemically modified C60 fullerene PCBM coupled through a composite recombination layer of single and multi walled carbon nanotubes and a dye sensitized solar cell (DSSC) in a series electrical configuration.

Within the illustration, light incident on the organic photovoltaic cell (OPV) generates excitons, an electron-hole pair bound through coulomb attraction on the PHT donor material. When PHT molecules are excited in the vicinity of an acceptor molecule, PCBM, more specifically when the excitation happens within the exciton diffusion length of an acceptor molecule, the bound electron is able to relax to a lower energy state on the fullerene molecule, illustrated as open circles. Due to phase separation within the polymer-fullerene photoactive layer, fullerene molecules arrange themselves forming charge percolation pathways, illustrated as a series of open circles, from polymer-fullerene interfaces to the carbon nanotube composite recombination sites. The light which was not absorbed within the OPV photo active layer can be absorbed within the DSSC photoelectrode. Light will travel through the carbon nanotube composite material and the hole transport material (SPIRO-MeOTAD) to the dye sensitized nanoporous Titanium Dioxide layer, light will generate a excited electron on the dye molecule which will be quickly transferred from the Ruthenium based dye to the Titanium dioxide nanoporous material and eventually to the cathode. The remaining hole will be transferred from the dye molecule to SPIRO-MeOTAD layer and will move towards the composite carbon nanotube recombination layer. Within the recombination layer, electrons from the OPV device will encounter holes from the DSSC device and non radiatively recombine. In this way the open circuit voltage will be increased to the sum of the two cells while the current at the electrodes will be limited to the smaller value of the two sub cells.

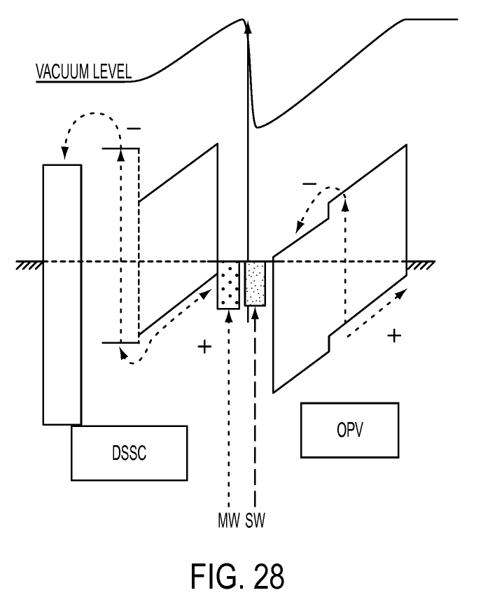

FIG. 28 demonstrates a hybrid tandem between OPV and DSSC cells connected by a carbon nanotube composite recombination site using an electrical band diagram with molecular orbital levels under illumination operating in the short circuit current regime. Light incident on the cell will pass through the transparent cathode of the DSSC cell as well as the nanoporous wide bandgap semiconducting material, such as titanium dioxide and incident on a dye molecule. Incident light will be absorbed on the dye molecule, causing an electron to be raised to an excited state. This excited electron will move to a lower energy state, the lowest unoccupied level of the nanoporous titanium dioxide and be collected on the cathode of the DSSC cell. The remaining hole will move from the dye molecule onto the hole transport material, such as SPIRO-MeOTAD and move under the influence of an electric field towards MW recombination center. The remaining light will pass through the transparent hole transport layer of the DSSC as well as both the MW and SW recombination materials and be incident on the donor material of the OPV. When the incident light is absorbed on the donor material such as PHT, an exciton will be formed. If the exciton is within a certain diffusion length of the acceptor material such as PCBM the exciton can relax to the lower energy level found on the acceptor, the hole will remain on the donor material. The hole will move through the polymeric network towards the anode under the influence of a strong internal electric field and be collected as usable current. The electron, which moved to the acceptor material will move under the influence of the internal electric field along chains of acceptor molecules that were formed due to the phenomenon of phase separation which happens between fullerenes and polymers towards the SW component of the recombination site. Electrons on the SW component and holes on the MW component of the recombination layer will meet and recombine.

### Example 10

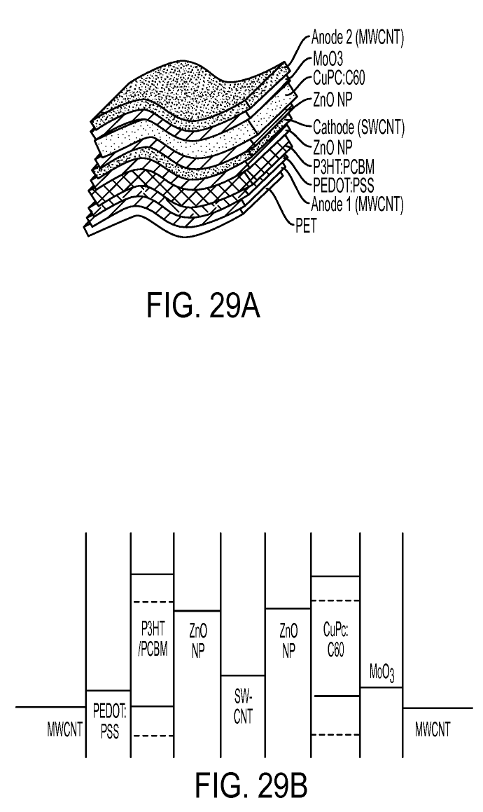

In FIG. 29A, we illustrate the parallel tandem architecture of a device consisted with two OPV sub-cells that connected in parallel with a common cathode interlayer. The parallel tandem solar cell is consisted of a polymeric sub-cell and a small molecule one. The flexible parallel tandem solar cell shown in this figure uses a MWCNT sheet bottom anode. A layer of PEDOT:PSS is deposited by spin coating to planarize the surface. The bottom sub cell donor-acceptor pair is consisted of the polymeric P3HT:PCBM blend.. A sheet of SWCNTs is used as the interlayer and are transferred on top the layer stack from free-standing state with our proprietary dry process. It is important for the tandem cell operation the addition of ZnO nanoparticle layers to facilitate electron collection from the two sub-cell towards the interlayer. The top sub cell's donor acceptor pair is made of a CuPc:C60 heterojunction. The second (top) anode is fabricated by thermal evaporation of MoO₃ and deposition of MWCNT sheet. Alternatively, we may replace CNTs with a metal layer (such as Al, Au or other) if a top transparent electrode is not required for the application.

The band diagram of the tandem device is shown in FIG. 29B. Under illumination light passes through the substrate and bottom transparent anode and is absorbed within the photo active layer of P3HT:PCBM creating an exciton on the donor material, this exciton will be separated into an electron on the acceptor and a hole on the polymer. Under the influence of the electric field generated by the common cathode and bottom anode the charges will move towards and collected to the respective electrodes, holes to common cathode and electrons to bottom anode. At the same time, light passes through the bottom semitransparent cell and interlayer. It is absorbed within the photo active layer of CuPc:C60 creating an exciton on the donor material, this exciton will be separated into an electron and a hole. Under the influence of the electric field generated by the common cathode and top anode the charges will move towards and collected to the respective electrodes, holes to common cathode and electrons to top anode.

1-30. (canceled)

31. A method of making a monolithic multi junction photovoltaic device comprising the steps of:
(a) providing a substrate and an electrode over the substrate;
(b) providing a photoactive absorbing layer disposed over the electrode;
(c) providing a charge collecting interlayer on top of the photoactive absorbing layer to form a bottom sub-cell; and
(d) providing an absorbing layer on top of the charge collecting interlayer to form a top sub-cell; and
(e) forming a multi-junction photovoltaic device.

32. The method of claim 31 wherein the top and bottom sub-cells are connected in parallel and the charge collecting interlayer is a common anode.

33. The method of claim 31 wherein the top and bottom sub-cells are connected in inverted parallel and the charge collecting interlayer is a common cathode.

34. A method of making a monolithic multi junction PV device capable of absorbing light through a top electrode comprising the steps of:
(a) providing a substrate and an electrode over the substrate;
(b) providing a first absorption layer disposed over the electrode;
(c) providing a first charge collecting interlayer over the first absorbing layer to form a bottom sub-cell;
(d) providing a second absorption layer disposed over the charge collecting interlayer;
(e) providing a second charge collecting interlayer over the second absorption layer to form a middle sub-cell; and
(f) providing a third absorption layer disposed over the second charge collecting interlayer to form a top sub-cell; and
(g) forming a multi-junction photovoltaic device.

35. The method of claim 34 wherein the first charge collecting interlayer is a common cathode for the bottom sub-cell and middle sub-cell and the second charge collecting interlayer is a common anode for the top and middle sub-cells.

36. The method of claim 34 wherein the first charge collecting interlayer is a common anode for the bottom sub-cell and middle sub-cell and the second charge collecting interlayer is a common cathode for the top and middle sub-cells.

37. The method of claim 31 wherein the electrode is an anode that comprises a metal, a metal oxide, a transparent conductive oxide, multi wall carbon nanotubes, or single wall carbon nanotubes.

38. The method of claim 31 wherein the electrode is a cathode comprises a metal, a metal oxide, a transparent conductive oxide, multi wall carbon nanotubes, or single wall carbon nanotubes.

39. The method of claim 31 wherein the charge collecting interlayer comprises multi wall carbon nanotubes, or single wall carbon nanotubes.

40. The method of claim 34 wherein the charge collecting interlayers comprise multi wall carbon nanotubes, or single wall carbon nanotubes.

41. The method of claim 34 wherein the top sub-cell, middle sub-cell and bottom sub-cell are selected from the group consisting of OPV, DSSC and inorganic solar cell.

42. A process for forming a multi-junction photovoltaic device, comprising:
forming a first single-junction photovoltaic cell on a substrate, including the steps of:
forming an electrode over the substrate,
forming a first photoactive absorbing layer disposed on top of the electrode;
forming a first charge collecting interlayer disposed on top of the first photoactive absorbing layer; and
forming at least one additional single-junction photovoltaic cell above the charge collecting interlayer.

43. The process of claim 42, wherein the step of forming at least one additional single-junction photovoltaic cell comprises:
forming a second photoactive absorbing layer on top of the first charge collecting interlayer; and
forming an electrode over the second photoactive absorbing layer.

44. A photovoltaic device comprising:
a substrate;
an electrode disposed on the substrate;
a photoactive absorbing layer disposed on top of the electrode;
a charge collecting interlayer disposed on the photoactive absorbing layer; and
at least one additional single-junction photovoltaic cell disposed on the charge collecting interlayer.

45. The photovoltaic device of claim 44, wherein the electrode comprises a metal, a metal oxide, a transparent conductive oxide, multi wall carbon nanotubes, or single wall carbon nanotubes.

46. The photovoltaic device of claim 44, wherein the charge collecting interlayer comprises multi wall carbon nanotubes, or single wall carbon nanotubes.
